(19) United States
(12) Patent Application Publication
(10) Pub. No.: US 2026/0157230 A1
(43) Pub. Date: Jun. 4, 2026

(54) SEMICONDUCTOR PACKAGE INCLUDING OPTICAL INTEGRATED CIRCUIT CHIP

(71) Applicant: Samsung Electronics Co., Ltd., Suwon-si (KR)

(72) Inventor: Junghoon KANG, Suwon-si (KR)

(73) Assignee: Samsung Electronics Co., Ltd., Suwon-si (KR)

(21) Appl. No.: 19/256,762

(22) Filed: Jul. 1, 2025

(30) Foreign Application Priority Data
Nov. 29, 2024 (KR) 10-2024-0175837

(51) Int. Cl. H01L 25/16; G02B 6/12; H01L 23/00; H01L 23/28; H01L 23/498

(52) U.S. Cl. CPC H10W 90/00; G02B 6/12002; H10W 74/00; H10W 90/701; H10W 90/722

(57) ABSTRACT

A semiconductor package includes a first semiconductor chip including first chip pads on a lower surface of the first semiconductor chip, a photonics chip including a photonic integrated circuit and second chip pads on an upper surface of the photonics chip, and first conductive pillars interposed between the first chip pads and the second chip pads.

### CROSS-REFERENCE TO RELATED APPLICATIONS

This application claims priority under 35 U.S.C. § 119 to Korean Patent Application No. 10-2024-0175837, filed on Nov. 29, 2024, in the Korean Intellectual Property Office, the disclosure of which is incorporated by reference herein in its entirety.

### BACKGROUND

### 1. Field

The present disclosure relates generally to semiconductor packages, and more particularly, to a semiconductor package including an optical integrated circuit chip.

### 2. Description of Related Art

The use of electronic devices such as smart phones, tablet personal computers (PCs), digital cameras, Moving Picture Experts Group (MPEG) Audio Layer 3(MP3 ) players, personal digital assistants (PDAs), and the like, may have increased. Such electronic devices may need and/or demand a relatively high-speed and/or relatively high-throughput processor in an attempt to provide functionality such as, but not limited to, multimedia processing, processing of various types of data at a relatively high speed and/or throughput, simultaneous execution of various application programs in the electronic devices, or the like.

The electronic devices may include semiconductor devices such as, but not limited to, working memories (e.g., dynamic random access memory (DRAM)), nonvolatile memories, application processors (AP), or the like to drive various application programs. Growing demand for processing increasing amounts of data by the electronic devices necessitates the use of memory devices with a relatively high capacity and/or a relatively high bandwidth. Accordingly, research is actively being conducted to replace the use of metal wiring for signal transmission with the use of optical signals.

To that end, mounting an optical transceiver and a switch application-specific integrated circuit (ASIC) chip on one substrate has been proposed. As the optical transceiver, a silicon photonics package is a module that forms optical components directly on a silicon-based die using a complementary metal-oxide-semiconductor (CMOS) process, and integrates electronic components that perform conversion processing between optical and electrical signals. Recently, in an environment where data traffic is increasing (e.g., in data centers and/or communication infrastructures), research on semiconductor packages containing photonics chips is being conducted.

### SUMMARY

One or more example embodiments of the present disclosure provide a miniaturized semiconductor package having a short signal transmission path, when compared to related semiconductor packers.

The present disclosure is not limited to the problems mentioned above, and other aspects not mentioned above may be apparent by those skilled in the art from the description below.

According to an aspect of the present disclosure, a semiconductor package includes a first semiconductor chip including first chip pads on a lower surface of the first semiconductor chip, a photonics chip including a photonic integrated circuit and second chip pads on an upper surface of the photonics chip, and first conductive pillars interposed between the first chip pads and the second chip pads.

According to an aspect of the present disclosure, a semiconductor package includes a first semiconductor chip including first chip pads on a lower surface of the first semiconductor chip, a second semiconductor chip horizontally spaced from the first semiconductor chip and including second chip pads on a lower surface of the second semiconductor chip, a photonics chip on the lower surfaces of the first semiconductor chip and the second semiconductor chip and including third chip pads on an upper surface of the photonics chip, an optical support block horizontally spaced apart from the first semiconductor chip and at least partially vertically overlapping the photonics chip, first conductive pillars interposed between the first chip pads and the third chip pads, second conductive pillars interposed between the second chip pads and the third chip pads, a first molding layer at least partially surrounding the first semiconductor chip, the second semiconductor chip, the first conductive pillars, and the second conductive pillars, and a second molding layer in contact with a lower surface of the first molding layer and at least partially surrounding the photonics chip.

According to an aspect of the present disclosure, a semiconductor package includes a first semiconductor chip including first chip pads on a lower surface of the first semiconductor chip, a second semiconductor chip horizontally spaced from the first semiconductor chip and including second chip pads on a lower surface of the second semiconductor chip, a photonics chip on the lower surfaces of the first semiconductor chip and the second semiconductor chip and including a photonic integrated circuit and third chip pads on an upper surface of the photonics chip, a third semiconductor chip horizontally spaced from the first semiconductor chip and including fourth chip pads on a lower surface of the third semiconductor chip, a bridge chip on the lower surfaces of the first semiconductor chip and the third semiconductor chip and including fifth chip pads on an upper surface of the bridge chip, first conductive pillars interposed between the first chip pads and the third chip pads, second conductive pillars interposed between the second chip pads and the third chip pads, third conductive pillars interposed between the fourth chip pads and the fifth chip pads, a redistribution layer on lower surfaces of the photonics chip and the bridge chip and including redistribution patterns coupled with the photonics chip and the bridge chip, a first molding layer at least partially surrounding the first semiconductor chip, the second semiconductor chip, the third semiconductor chip, the first conductive pillars, the second conductive pillars, and the third conductive pillars, a second molding layer in contact with a lower surface of the first molding layer and at least partially surrounding the photonics chip, the bridge chip, and a conductive post, and the conductive post horizontally spaced from the photonics chip and at least partially penetrating the second molding layer.

According to an aspect of the present disclosure, a method of manufacturing a semiconductor package may include forming first, second, and third conductive pillars on a carrier substrate, mounting first, second, and third semiconductor chips on the first, second, and third conductive pillars, respectively, forming a first molding layer surrounding the first, second, and third semiconductor chips and the first, second, and third conductive pillars, mounting a photonics chip on lower surfaces of the first and second semiconductor chips, after removing the carrier substrate, wherein the photonics chip is bonded to the first and second conductive pillars, mounting a bridge chip on lower surfaces of the second and third semiconductor chips, wherein the bridge chip is bonded to the third conductive pillars, forming a second molding layer surrounding the photonics chip and the bridge chip and in contact with a lower surface of the first molding layer, and forming a redistribution layer including redistribution patterns connected to the photonics chip and the bridge chip on a lower surface of the second molding layer.

In some embodiments, the method may further include attaching an optical support block on the carrier substrate before the forming of the first molding layer.

In some embodiments, the lower surface of the first molding layer is substantially coplanar with a lower surface of the optical support block.

In some embodiments, the method may further include forming a transparent underfill layer between an upper surface of the photonics chip and a lower surface of the optical support block before the forming of the second molding layer.

In some embodiments, the forming of the first, second, and third conductive pillars includes forming connection pads.

In some embodiments, the method may further include forming conductive posts connected to the connection pads, before or after the mounting of the photonics chip and the bridge chip.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1 is a cross-sectional view of a semiconductor package, according to embodiments of the present disclosure;

FIG. 2A is an enlarged view of portion P1 of FIG. 1, according to embodiments of the present disclosure;

FIG. 2B is an enlarged view of portion P2 of FIG. 1, according to embodiments of the present disclosure;

FIGS. 3 to 7 are cross-sectional views of semiconductor packages, according to various embodiments of the present disclosure; and

FIGS. 8 to 13 are views illustrating a method of manufacturing a semiconductor package, according to embodiments of the present disclosure.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, or the like may be replaced with terms, such as “first,” “second,” “third” to be used to describe relative positions of elements. The terms “first,” “second,” “third” may be used to describe various elements but the elements are not limited by the terms and a “first element” may be referred to as a “second element”. Alternatively or additionally, the terms “first”, “second”, “third”, or the like may be used to distinguish components from each other and do not limit the present disclosure. For example, the terms “first”, “second”, “third”, or the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

Hereinafter, a semiconductor package, according to embodiments of the present disclosure, and a manufacturing method thereof are described with reference to the accompanying drawings.

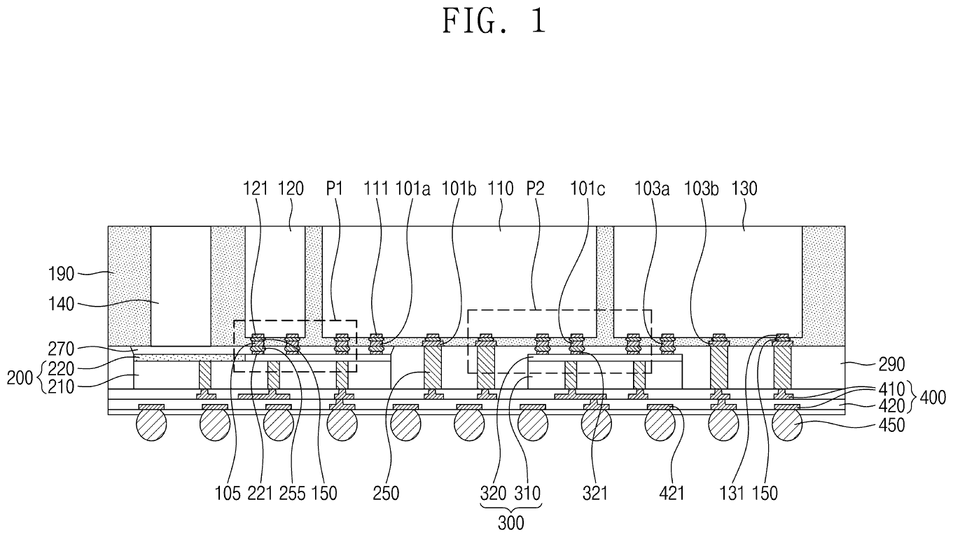

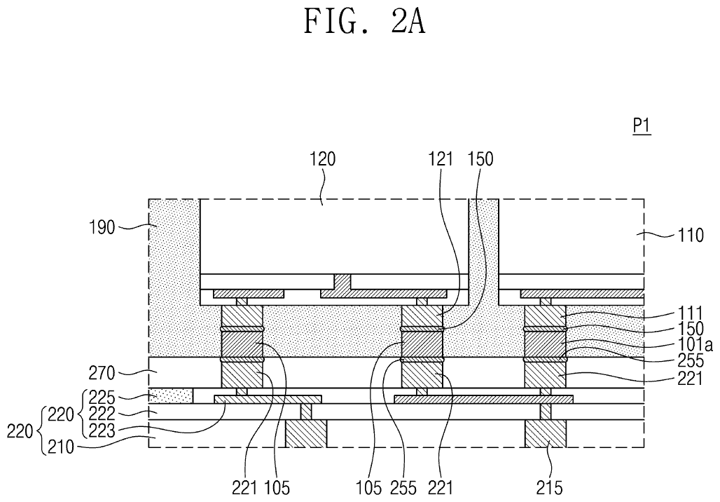

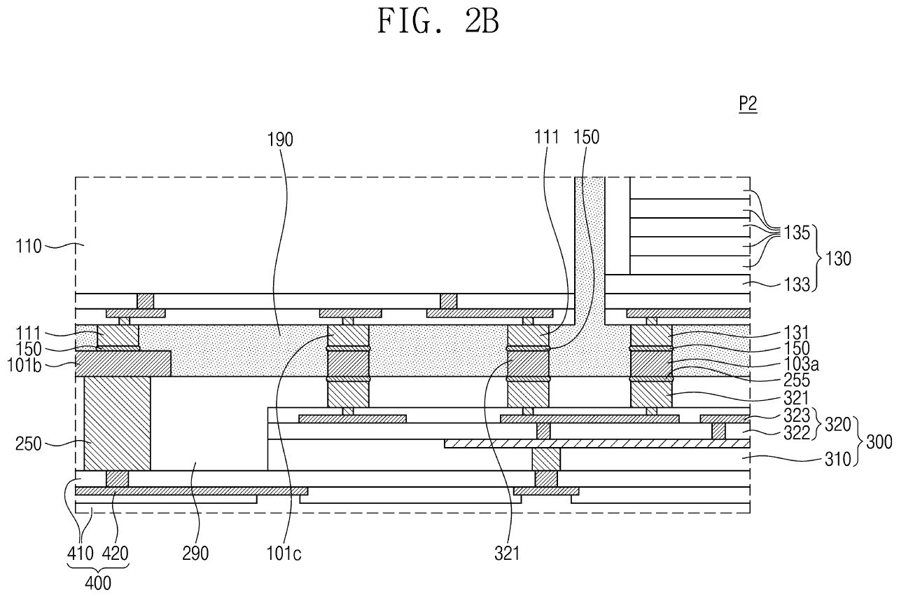

FIG. 1 is a cross-sectional view of a semiconductor package, according to embodiments of the present disclosure. FIG. 2A is an enlarged view of portion P1 of FIG. 1, according to embodiments of the present disclosure. FIG. 2B is an enlarged view of portion P2 of FIG. 1, according to embodiments of the present disclosure.

Referring to FIG. 1, a semiconductor package, according to embodiments, may include a plurality of semiconductor chips (e.g., a first semiconductor chip 110, a second semiconductor chip 120, and a third semiconductor chip 130), an optical support block 140, a photonics chip 200, and a bridge chip 300.

The first semiconductor chip 110 may include an integrated circuit integrated on a semiconductor substrate such as, but not limited to, silicon (Si). The first semiconductor chip 110 may include first chip pads 111 on a lower surface thereof. The first chip pads 111 may be electrically connected to the integrated circuits.

The first semiconductor chip 110 may include a logic chip, a buffer chip, or a system on chip (SoC). For example, the first semiconductor chip 110 may be and/or may include an application-specific integrated circuit (ASIC) chip or an application processor (AP) chip. The ASIC chip may include an application specific integrated circuit (ASIC). The first semiconductor chip 110 may be and/or may include a logic chip including a processor such as, but not limited to, a central processing unit (CPU), a graphic processing unit (GPU), a mobile application, a digital signal processor (DSP), or the like.

The second semiconductor chip 120 may be disposed to be horizontally spaced apart from the first semiconductor chip 110. The second semiconductor chip 120 may include second chip pads 121 electrically connected to an electronic integrated circuit on a lower surface thereof.

The second semiconductor chip 120 may include an electronic integrated circuit (EIC) including electronic components that may perform conversion between an optical signal and an electrical signal and/or processing for input/output of an electrical signal.

The second semiconductor chip 120 may include a logic circuit configured to amplify an electrical signal output by a photodetector, to output the electrical signal to the outside, and to drive an optical modulator in response to an electrical signal input from the outside.

The second semiconductor chip 120 may include a current-to-voltage converter that may convert a current signal output by the photodetector into a voltage signal, an output driver that may output the converted electric signal to the outside, an input buffer that may receive an electric signal from the outside, a controller that may control a light source, and a modulator driver that may drive an optical modulator.

The third semiconductor chip 130 may be disposed to be horizontally spaced apart from the first semiconductor chip 110. The third semiconductor chip 130 may include third chip pads 131 on a lower surface thereof. The third semiconductor chip 130 may be and/or may include a memory chip such as, but not limited to, dynamic random-access memory (DRAM), static random-access memory (SRAM), magneto-resistive random access memory (MRAM), flash memory, or the like.

Referring to FIG. 2B, the third semiconductor chip 130 may include a buffer die 133 and a plurality of core dies 135 that may be vertically stacked on the buffer die 133. The third chip pads 131 may be substantially provided on the lower surface of the buffer die 133. As used herein, the buffer die 133 may be referred to as an interface die, a base die, a logic die, or a master die, and each of the core dies 135 may be referred to as a memory die, or a slave die.

The buffer die 133 and the core dies 135 may be electrically connected through through-silicon vias (TSVs). Accordingly, the third semiconductor chip 130 may include a three-dimensional (3D) memory structure in which a plurality of dies (e.g., the buffer die 133 and the core dies 135) may be stacked. For example, the third semiconductor chip 130 may be implemented based on a high-bandwidth memory (HBM) and/or a hybrid memory cube (HMC) standard.

The buffer die 133 may receive commands, addresses, and/or data from the memory controller, and may provide the received commands, addresses, and/or data to the core dies 135. The buffer die 133 may buffer the commands, addresses, and/or data, and thus, the memory controller may interface with the core dies 135 by driving only a load of the buffer die 133.

The core dies 135 may be vertically stacked on the buffer die 133. In embodiments, the number of core dies 135 may be variously changed. For example, a semiconductor device may include eight (8), twelve (12), or sixteen (16) core dies without departing from the scope of the present disclosure.

Each of the core dies 135 may include through-silicon vias (TSVs) and may be electrically connected to the buffer die 133 through the through-silicon vias (TSVs). Each of the core dies 135 may include a memory cell array, a column decoder, a row decoder, a sense amp, a write driver, and an input/output buffer.

In some embodiments, an adhesive layer may be provided between the plurality of dies 133 and 135. The adhesive layer may include a non-conductive film (NCF). The adhesive layer may be interposed between the chip bumps of the plurality of dies 133 and 135 to prevent and/or to reduce a possibility of an electrical short between the chip bumps.

A photonics chip 200 may be disposed on the lower surfaces of the first and second semiconductor chips 110 and 120. A portion of the photonics chip 200 may vertically overlap a portion of the first semiconductor chip 110, and the other portion of the photonics chip 200 may vertically overlap a portion of the second semiconductor chip 120.

The photonics chip 200 may include fourth chip pads 221 on an upper surface thereof. Some of the fourth chip pads 221 of the photonics chip 200 may correspond to the first chip pads 111 of the first semiconductor chip 110, and others of the fourth chip pads 221 may correspond to the second chip pads 121 of the second semiconductor chip 120.

The photonics chip 200 may include a base layer 210 and an element layer 220. The base layer 210 may include a semiconductor substrate, and the semiconductor substrate may include an active surface and an inactive surface opposite thereto, and the element layer 220 may be formed on the active surface of the semiconductor substrate. The element layer 220 may include a photonic integrated circuit. The photonic integrated circuit may receive an optical signal, perform computational processing, and convert the optical signal into an electrical signal.

The element layer 220 of the photonics chip 200 may include an optical waveguide, a grating coupler, an optical modulator, a photodetector, or the like.

The photonics chip 200 may include the fourth chip pads 221 in the element layer 220. The fourth chip pads 221 may be electrically connected to the photonic integrated circuit. The fourth chip pads 221 may be exposed on the upper surface of the photonics chip 200. The fourth chip pads 221 may include a conductive material such as, but not limited to, copper (Cu).

Referring to FIG. 2A, the element layer 220 may include insulating layers 222, wiring patterns 223, and an optical receiver 225 disposed on the base layer 210.

The optical receiver 225 may receive an optical signal that has traveled through the optical waveguide. The optical receiver 225 may be formed by a complementary metal-oxide-semiconductor (CMOS) process. The optical receiver 225 may be configured to convert an optical signal received through an optical fiber array into an electrical signal, to transmit the converted signal to electronic components, and to transmit an optical signal emitted from a light source element through the optical fiber array in response to the control of the electronic components.

According to some embodiments, first conductive pillars 101a may be interposed between the first chip pads 111 and the fourth chip pads 221 of the photonics chip 200.

The first conductive pillars 101a may have a cylindrical shape. The first conductive pillars 101a may include a conductive material (e.g., a metal), and may be formed of at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or a metal alloy thereof.

For example, each of the first conductive pillars 101a may have a width of about 20 micrometer (μm) to about 40 μm. An arrangement of the first conductive pillars 101 a may be variously changed depending on an arrangement of the first chip pads of the first semiconductor chip 110.

First solder layers 150 may be interposed between the first conductive pillars 101a and the first chip pads 111, and second solder layers 255 may be interposed between the first conductive pillars 101a and the fourth chip pads 221 of the photonics chip 200.

The first and second solder layers 150 and 255 may include a conductive material, such as, but not limited to, at least one of tin (Sn), silver (Ag), or lead (Pb).

According to some embodiments, second conductive pillars 105 may be interposed between the second chip pads 121 and the fourth chip pads 221 of the photonics chip 200.

The second conductive pillars 105 may have a cylindrical shape. The second conductive pillars 105 may include a conductive material (e.g., a metal), and may be formed of at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or a metal alloy thereof.

For example, each of the second conductive pillars 105 may have a width of about 20 μm to about 40 μm. An arrangement of the second conductive pillars 105 may be variously changed depending on an arrangement of the second chip pads 121 of the second semiconductor chip 120.

The first solder layers 150 may be interposed between the second conductive pillars 105 and the second chip pads 121, and the second solder layers 255 may be interposed between the second conductive pillars 105 and the fourth chip pads 221 of the photonics chip 200.

According to some embodiments, the optical receiver 225 of the photonics chip 200 may include the optical support block 140 disposed thereon, through which a light source may be capable of being transmitted.

In some embodiments, the optical receiver 225 of the photonics chip 200 may include a grating coupler, and the optical support block 140 may be disposed corresponding to the grating coupler.

The optical support block 140 may be formed of various materials depending on a wavelength of light incident on the photonics chip 200. For example, the optical support block 140 may transmit light having a wavelength of about 700 nanometers (nm) to about 1500 nm.

The optical support block 140 may be formed of a dielectric material. The optical support block 140 may be formed of a transparent and/or nearly (substantially) transparent material. The optical support block 140 may include one or more materials, such as, but not limited to, silicon (e.g., silicon wafer, bulk silicon, or the like), silicon oxide (SiO₂), silicon oxynitride (SiOₓN_{y}), silicon nitride (Si₃N₄), glass, or another type of material.

An upper surface of the optical support block 140 may be substantially coplanar with the upper surfaces of the plurality of semiconductor chips 110 to 130.

The bridge chip 300 may be disposed on the lower surfaces of the first and third semiconductor chips 110 and 130. The bridge chip 300 may include fifth chip pads 321 on an upper surface thereof.

A portion of the bridge chip 300 may be vertically overlapped with a portion of the first semiconductor chip 110, and another portion of the bridge chip 300 may be vertically overlapped with a portion of the third semiconductor chip 130.

Referring to FIG. 2B, the bridge chip 300 may include a bridge base layer 310 and a bridge wiring layer 320.

The bridge base layer 310 may include a semiconductor substrate. For example, the bridge base layer 310 may be a semiconductor substrate such as, but not limited to, a semiconductor wafer. The bridge base layer 310 may be and/or may include a silicon substrate, a silicon-on-insulator (SOI) substrate, a germanium (Ge) substrate, a germanium-on-insulator (GOI) substrate, a silicon-germanium (Si-Ge) substrate, a group III-V semiconductor substrate, or a substrate of an epitaxial thin layer obtained by performing selective epitaxial growth (SEG). The bridge base layer 310 may include, for example, at least one of silicon (Si), germanium (Ge), silicon-germanium (Si-Ge), gallium arsenide (GaAs), indium gallium arsenide (InGaAs), aluminum gallium arsenide (AlₓGa₁₋ₓAs), or a mixture thereof.

The bridge wiring layer 320 may be disposed on an upper surface of the bridge base layer 310. For example, the bridge wiring layer 320 may include a bridge insulating pattern 322 and a bridge wiring pattern 323 formed on an upper surface of the bridge base layer 310. The bridge wiring layer 320 may further include a circuit pattern or a protective layer, if necessary.

The bridge insulating pattern 322 may include an insulating material. For example, the bridge insulating pattern 322 may include silicon oxide (SiO₂), silicon nitride (Si₃N₄), silicon oxynitride (SiOₓN_{y}), silicon carbon nitride (SiCN), or an insulating polymer. Alternatively or additionally, the bridge insulating pattern 322 may include an insulating polymer or a photoimageable dielectric (PID). For example, the photoimageable dielectric may include at least one of a photosensitive polyimide, a polybenzoxazole (PBO), a phenol-based polymer, or a benzocyclobutene-based polymer.

The bridge wiring pattern 323 may be provided in the bridge insulating pattern 322. The bridge wiring pattern 323 may be a configuration for electrical connection between the first semiconductor chip 110 and the third semiconductor chip 130. The bridge wiring pattern 323 may include a conductive material. For example, the bridge wiring pattern 323 may include, but not be limited to, copper (Cu), aluminum (Al), or the like.

A density of wirings in the bridge chip 300 may be greater than a density of wirings in a redistribution layer 400. An integration of the fifth chip pads 321 may be greater than an integration of substrate pads of the redistribution layer 400 in a predetermined area.

The number of fifth chip pads 321 provided per unit area may be greater than the number of connection pads 421 of the redistribution layer 400 provided per unit area.

According to embodiments, third conductive pillars 101c may be interposed between the first chip pads 111 of the first semiconductor chip 110 and the fifth chip pads 321 of the bridge chip 300.

The third conductive pillars 101c may have a cylindrical shape. The third conductive pillars 101c may include a conductive material (e.g., a metal), and may be formed of at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or a metal alloy thereof.

An arrangement of the third conductive pillars 101c may be variously changed depending on an arrangement of the first chip pads 111 of the first semiconductor chip 110.

The first solder layers 150 may be interposed between the third conductive pillars 101c and the first chip pads 111, and the second solder layers 255 may be interposed between the third conductive pillars 101c and the fifth chip pads 321 of the bridge chip 300.

According to embodiments, the fourth conductive pillars 103a may be interposed between the third chip pads 131 of the third semiconductor chip 130 and the fifth chip pads 321 of the bridge chip 300.

The fourth conductive pillars 103a may have a cylindrical shape. The fourth conductive pillars 103a may include a conductive material (e.g., a metal), and may be formed of at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or a metal alloy.

For example, each of the fourth conductive pillars 103a may have a width of about 20 μm to about 40 μm. An arrangement of the fourth conductive pillars 103a may be variously changed depending on an arrangement of the third chip pads 131 of the third semiconductor chip 130.

Some of the first chip pads 111 of the first semiconductor chip 110 may be connected to first connection pads 101b by the first solder layers 150. Some of the third chip pads 131 of the third semiconductor chip 130 may be connected to second connection pads 103b by the first solder layers 150. The first and second connection pads 101b and 103b may include a substantially similar and/or the same conductive material as the first to fourth conductive pillars 101a to 105. A thickness of each of the first and second connection pads 101b and 103b may be substantially similar and/or the same thickness as a thickness of each of the first to fourth conductive pillars 101a to 105. A width of each of the first and second connection pads 101b and 103b may be greater than a width of each of the first to fourth conductive pillars 101a to 105.

Conductive posts 250 may be disposed on the first connection pads 101b and the second connection pads 103b. The conductive posts 250 may be directly connected to the first and second connection pads 101b and 103b.

The conductive posts 250 may electrically connect the redistribution layer 400 and the first and third semiconductor chips 110 and 130. The conductive posts 250 may have a pillar shape extending in a vertical direction. However, embodiments of the present disclosure are not limited thereto, and the conductive posts 250 may be provided in various shapes for vertical connection. The conductive posts 250 may have a constant width. The conductive posts 250 may include a conductive material. For example, the conductive posts 250 may include a metal material such as, but not limited to, copper (Cu) or tungsten (W).

A first molding layer 190 may surround the plurality of semiconductor chips 110 to 130. An upper surface of the first molding layer 190 may be substantially coplanar with upper surfaces of the plurality of semiconductor chips 110 to 130. A lower surface of the first molding layer 190 may be substantially coplanar with lower surfaces of the first to fourth conductive pillars 101a to 105. The first molding layer 190 may fill a space between the first conductive pillars 101a, between the second conductive pillars 105, between the third conductive pillars 101c, and between the fourth conductive pillars 103a. The first molding layer 190 may directly cover sidewalls of the first, second, and third conductive pillars 101a, 105, and 101c. The lower surface of the first molding layer 190 may be substantially coplanar with lower surfaces of the first and second connection pads 101b and 103b. In addition, the lower surface of the first molding layer 190 may be in contact with an upper surface of a second molding layer 290.

The first molding layer 190 may include an insulating polymer material. For example, the first molding layer 190 may include an epoxy resin composition. The epoxy resin composition may include epoxy, a curing agent, and a filler. The first molding layer 190 may include, for example, an epoxy molding compound (EMC). However, embodiments of the present disclosure are not limited in this regard, and the material of the first molding layer 190 is not limited to EMC.

The second molding layer 290 may surround the photonics chip 200 and the bridge chip 300. The second molding layer 290 may be disposed between the first molding layer 190 and the redistribution layer 400 when viewed in a vertical direction.

The conductive posts 250 may be disposed in the second molding layer 290. The second molding layer 290 may seal sidewalls of the conductive posts 250 and sidewalls of the photonics chip 200 and the bridge chip 300. The second molding layer 290 may include an insulating polymer, such as, but not limited to, an EMC.

In some embodiments, the semiconductor package may further include a transparent underfill layer 270 that may transmit light. The transparent underfill layer 270 may fill a space between a lower surface of the optical support block 140 and a lower surface of the photonics chip 200. The transparent underfill layer 270 may surround the fourth chip pads 221 of the photonics chip 200.

The transparent underfill layer 270 may include, for example, epoxy, silicone, polymethylmethacrylate (PMMA), polyethylene, polystyrene, or a combination thereof, and may generally include epoxy, for example.

The redistribution layer 400 may be provided on the lower surface of the second molding layer 290. The redistribution layer 400 may include a redistribution insulating layer 410 and a redistribution pattern 420. The redistribution insulating layer 410 may be a single layer or a plurality of stacked layers. In some embodiments, among the redistribution insulating layers 410, an interface between adjacent two layers may not be distinguished.

Although FIG. 2B depicts a particular number

Although FIG. 2B depicts a stack consisting of a particular number of redistribution insulating layers 410, embodiments of the present disclosure are not limited to that shown and the number of layers may be modified in various ways. The redistribution insulating layer 410 may include an insulating polymer or a photoimageable dielectric (PID). For example, the photoimageable polymer may include at least one of a photoimageable polyimide, a polybenzoxazole (PBO), a phenol-based polymer, or a benzocyclobutene-based polymer.

The redistribution pattern 420 may be disposed in the redistribution insulating layer 410. A plurality of redistribution patterns 420 may be provided. The redistribution pattern 420 may include a conductive material, such as, but not limited to, at least one of copper (Cu), tungsten (W), titanium (Ti), or the like. The redistribution patterns 420 may be electrically connected to the photonics chip 200, the conductive posts 250, and the bridge chip 300.

Connection terminals 450 may be attached to the connection pads 421 of the redistribution layer 400. The connection terminals 450 may include solder balls, or solder bumps, or the like.

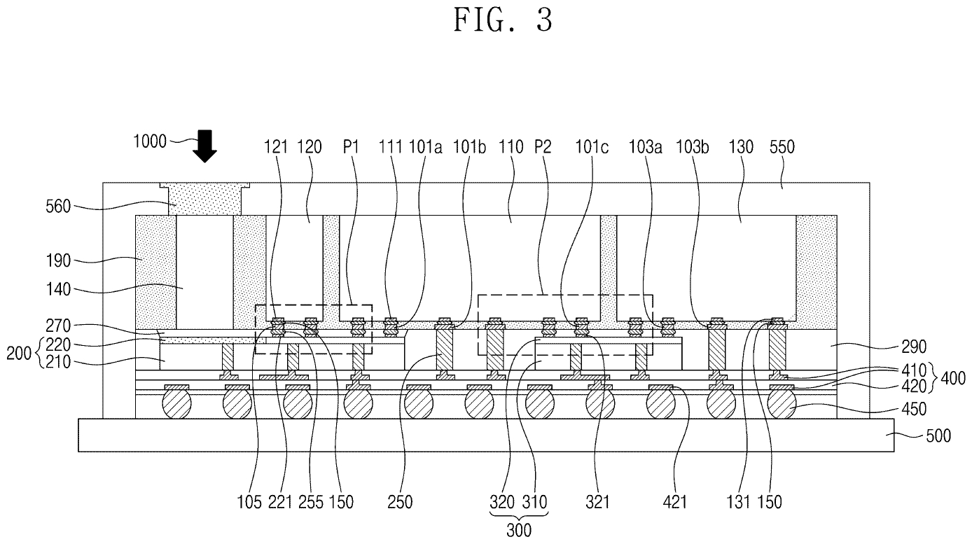

FIGS. 3 to 7 are cross-sectional views of semiconductor packages, according to various embodiments of the present disclosure. The semiconductor packages of FIGS. 3 to 7 may include and/or may be similar in many respects to the semiconductor packages described above with reference to FIGS. 1, 2A, and 2B, and may include additional features not mentioned above. Consequently, repeated descriptions of the semiconductor packages of FIGS. 3 to 7 described above with reference to FIG. ## may be omitted for the sake of brevity.

Referring to FIG. 3, the connection terminals 450 of the semiconductor package, according to the embodiments described with reference to FIG. 1, may be attached to an upper surface of a package substrate 500.

The semiconductor package may be mounted on the package substrate 500 in a flip chip manner. The package substrate 500 may include a printed circuit board (PCB) having a signal pattern on an upper surface thereof. Alternatively, the package substrate 500 may have a structure in which an insulating layer and a wiring layer are alternately stacked. The package substrate 500 may include pads disposed on the upper surface thereof.

External terminals may be disposed below the package substrate 500. The external terminals may include solder balls and/or solder bumps, and the semiconductor package may be provided in a form of a ball grid array (BGA), a fine ball-grid array (FBGA), or a land grid array (LGA) depending on the type and arrangement of the external terminals.

A metal lid 550 may be attached to the package substrate 500. The metal lid 550 may cover the semiconductor package, and may have an opening corresponding to the optical support block 140. A lens 560 may be coupled to the opening of the metal lid 550.

An optical fiber 1000 may be attached to the metal lid 550 in some embodiments. The optical fiber 1000 may be attached to an upper portion of the lens 560 and may be fixed using an optical adhesive or a socket.

An optical signal may be output or input through the optical fiber. The optical fiber may be optically connected to optical elements in the photonics chip 200.

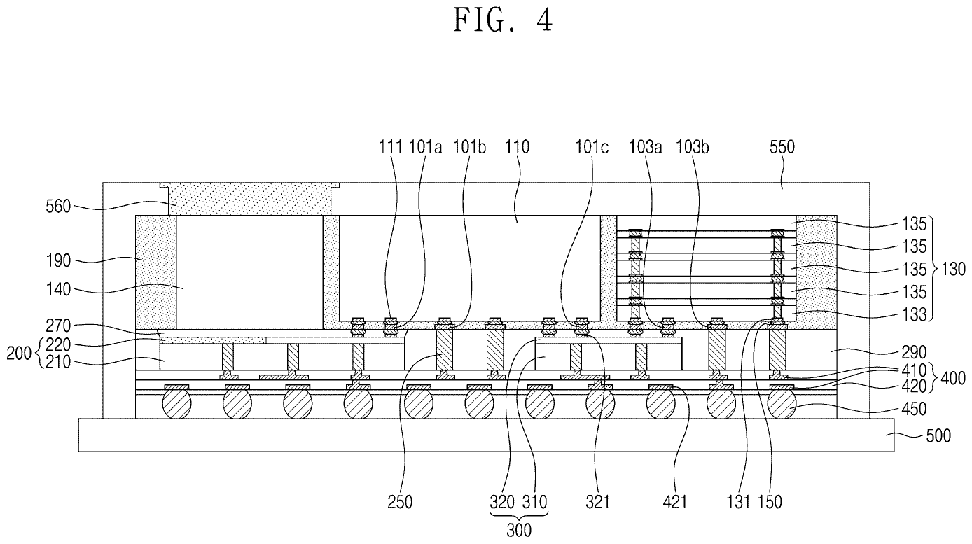

Referring to FIG. 4, the photonics chip 200 may include a photonic integrated circuit and an electronic integrated circuit (EIC).

The photonics chip 200 may include an optical waveguide, a grating coupler, an optical modulator, and a photodetector. In addition, the photonics chip 200 may further include a current-to-voltage converter that may convert a current signal output by a photodetector into a voltage signal, an output driver that may output the converted electric signal to the outside, an input buffer that may receive an electric signal from the outside, a controller that may control a light source, and a modulator driver that may drive an optical modulator.

That is, the photonics chip 200 may include an input/output (I/O) interface between optical signals and electric signals and electronic circuits for controlling the operation of photonic components.

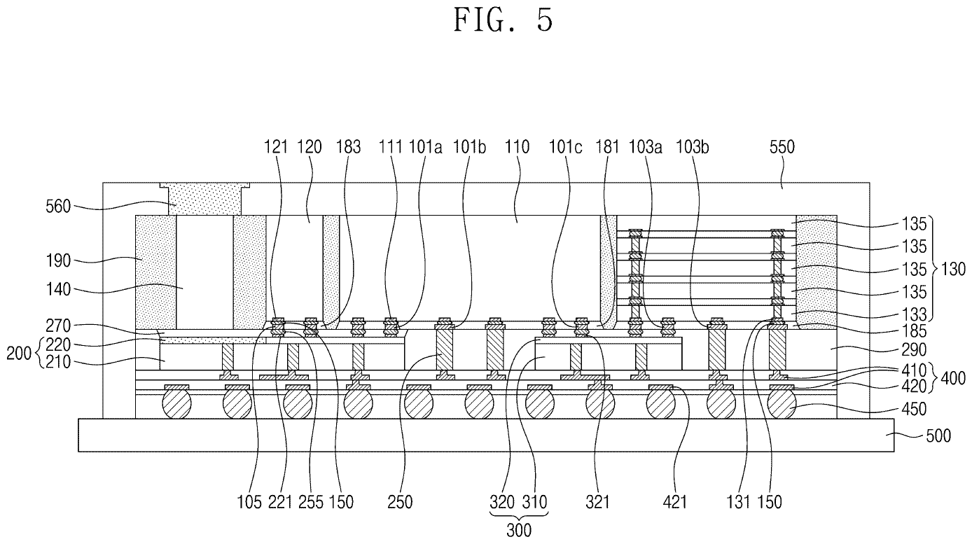

Referring to FIG. 5, a first underfill layer 181 may fill a space between the upper surface of the first semiconductor chip 110 and the second molding layer 290. The first underfill layer 181 may fill a space between the first conductive pillars 101a, between the third conductive pillars 101c, and between the first connection pads 101b.

In addition, a second underfill layer 183 may be interposed between the second semiconductor chip 120 and the photonics chip 200. The second underfill layer 183 may fill a space between the second conductive pillars 105.

A third underfill layer 185 may fill a space between the third semiconductor chip and the second molding layer 290. The third underfill layer 185 may fill a space between the fourth conductive pillars 103a and between the second connection pads 103b.

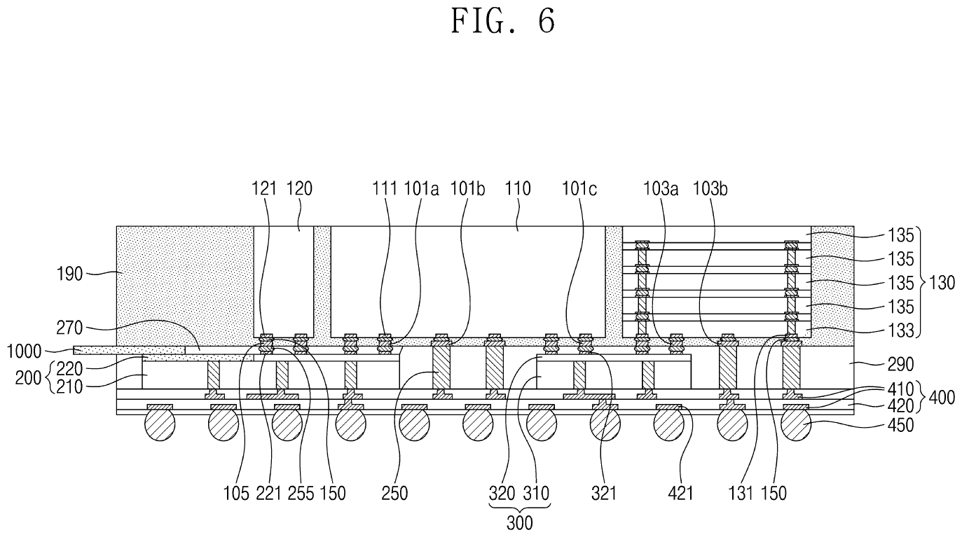

Referring to FIG. 6, in an embodiment described with reference to FIG. 1, the optical support block may be omitted. A portion of the photonics chip 200 may overlap the first molding layer 190, and an optical fiber 1000 may be coupled at an edge portion of the photonics chip 200.

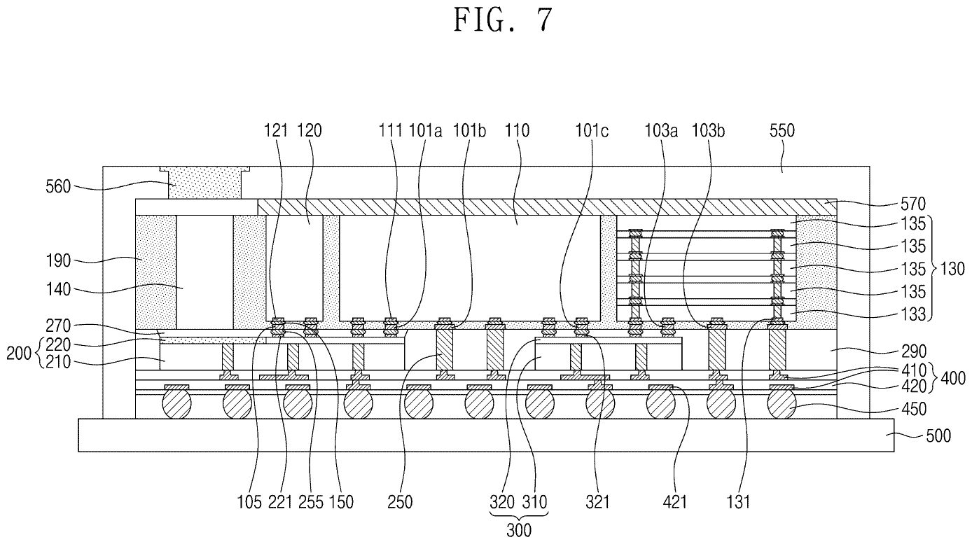

Referring to FIG. 7, a semiconductor package, according to embodiments, may include a heat dissipation member 570. The heat dissipation member 570 may be disposed on upper surfaces of the plurality of semiconductor chips 110 to 130. The heat dissipation member 570 may include, for example, a thermal interface material (TIM), or a heat sink compound.

The heat dissipation member 570 may include, for example, a heat sink, a liquid cooling structure, or another heat dissipation structure formed of any suitable materials, such as, but not limited to, a semiconductor (e.g., a silicon wafer, bulk silicon, or the like), a dielectric (e.g., a bulk oxide, or the like), or a metal.

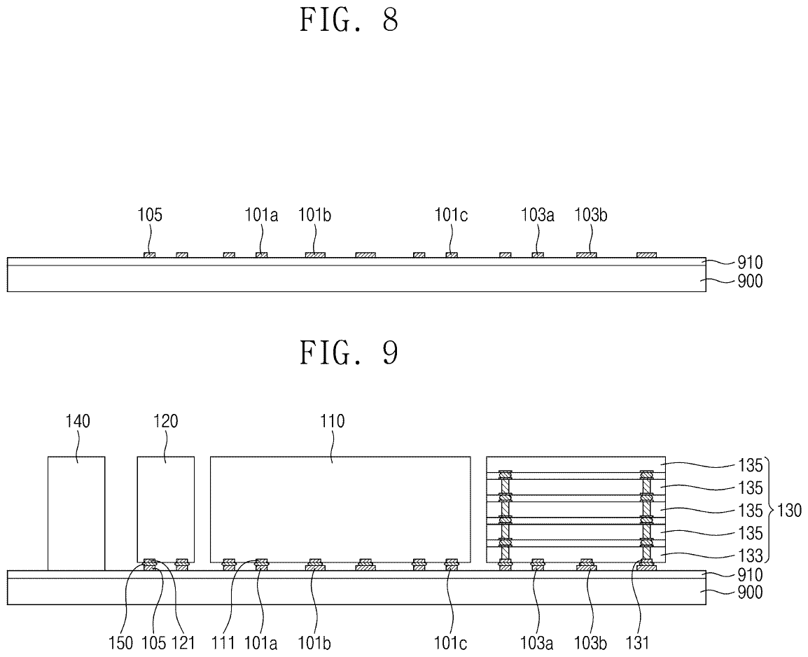

FIGS. 8 to 13 are views illustrating a method of manufacturing a semiconductor package, according to embodiments of the present disclosure.

Referring to FIG. 8, a carrier substrate 900 may be provided. The carrier substrate 900 may be a conductive substrate including a glass substrate, a ceramic substrate, a silicon wafer, or a metal.

An adhesive layer 910 may be provided on an upper surface of the carrier substrate 900. The adhesive layer 910 may include a polymeric material. For example, the adhesive layer 910 may include a light-to-heat-conversion (LTHC) release coating material and may be thermally-released by heating. As another example, the adhesive layer may include a ultraviolet (UV) adhesive that may be released by UV light.

First conductive pillars 101a, second conductive pillars 105, third conductive pillars 101c, fourth conductive pillars 103a, and first and second connection pads 101b and 103b may be formed on the adhesive layer 910.

For example, the forming of the first to fourth conductive pillars 101a to 105, and first and second connection pads 101b and 103b may include depositing a conductive material on the adhesive layer 910 and patterning the conductive material. In an embodiment, a metal seed layer may be further formed before depositing the conductive material.

As another example, the forming of the first to fourth conductive pillars 101a to 105 and the first and second connection pads 101b and 103b may include forming a sacrificial layer on a release layer, forming openings exposing the release layer below the sacrificial layer, filling the openings with a conductive material, and then removing the sacrificial layer.

The first to fourth conductive pillars 101a to 105 and the first and second connection pads 101b and 103b may be formed by an electrochemical plating process, an electroless plating process, a physical vapor deposition (PVD) process, a chemical vapor deposition (CVD) process, a spin-on process, or a combination thereof.

The first to fourth conductive pillars 101a to 105 and the first and second connection pads 101b and 103b may include, for example, copper (Cu), aluminum (Al), tungsten (W), nickel (Ni), titanium (Ti), titanium nitride (TiN), tantalum (Ta), tantalum nitride (TaN), gold (Au), or a combination thereof.

The first to fourth conductive pillars 101a to 105 and the first and second connection pads 101b and 103b may be and/or may include bonding pads, solder bumps, conductive pads, or conductive pillars. However, embodiments of the present disclosure are not limited in this regard. That is, an arrangement, shape, or size of the connection pads may be variously changed depending on a type of die or chip connected thereto.

Referring to FIG. 9, plurality of semiconductor chips 110 to 130 may be mounted and/or bonded on the first to fourth conductive pillars 101a to 105 and the first and second connection pads 101b and 103b. As described above, the plurality of semiconductor chips 110 to 130 may include first to third chip pads 111 to 131 on lower surfaces thereof, respectively.

Mounting the plurality of semiconductor chips 110 to 130 may include forming first solder layers 150 between the first to third chip pads 111 to 131 and the corresponding first to fourth conductive pillars 101a to 105, and the first and second connection pads 101b and 103b.

The first to third chip pads 111 to 131 may be bonded to the first to fourth conductive pillars 101a to 105 by the first solder layers 150. The first to third chip pads 111 to 131 may be connected to the first to fourth conductive pillars 101a to 105 by a thermo-compression bonding (TCB) manner.

Furthermore, an optical support block 140 may be attached onto the adhesive layer 910 and may be horizontally spaced apart from the second semiconductor chip 120.

The optical support block 140 may be formed of a transparent material or a nearly transparent material. The optical support block 140 may include, for example, silicon (e.g., silicon wafer, bulk silicon, or the like), silicon oxide (SiO₂), silicon oxynitride (SiOₓN_{y}), silicon nitride (Si₃N₄), glass, aluminum oxide (Al₂O₃), or a combination thereof.

An upper surface of the optical support block 140 may be substantially coplanar with upper surfaces of the plurality of semiconductor chips 110 to 130.

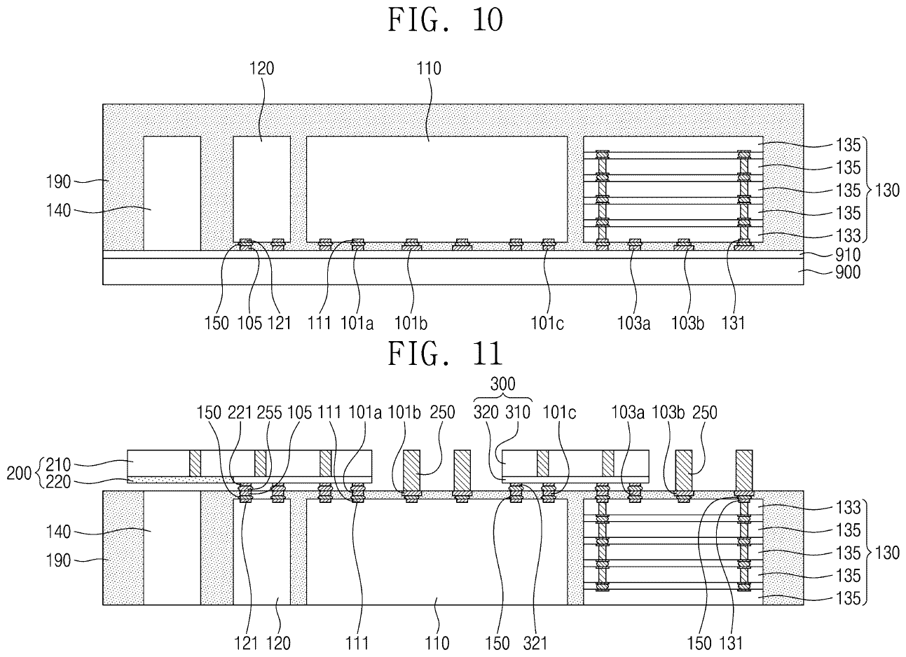

Referring to FIG. 10, a first molding layer 190 may be formed on the carrier substrate 900. The first molding layer 190 may cover the adhesive layer 910, the plurality of semiconductor chips 110 to 130, and the optical support block 140. The first molding layer 190 may cover the upper surfaces and sidewalls of the plurality of semiconductor chips 110 to 130 and the upper surface and sidewalls of the optical support block 140. The first molding layer 190 may include an insulating polymer such as, but not limited to, an EMC.

Referring to FIG. 11, a grinding process may be performed on the first molding layer 190. A portion of the upper portion of the first molding layer 190 may be removed. The grinding process may be performed until the upper surfaces of the plurality of semiconductor chips 110 to 130 and the upper surface of the optical support block 140 are exposed. An upper surface of the first molding layer 190 may be substantially coplanar with the upper surfaces of the plurality of semiconductor chips 110 to 130 and the upper surface of the optical support block 140.

Subsequently, the carrier substrate 900 may be removed and/or de-bonded. To remove the carrier substrate 900, an optical beam, such as, but not limited to, a laser beam, may be irradiated onto the adhesive layer 910, which may decompose the adhesive layer 910 with the heat of the optical beam. Accordingly, the carrier substrate 900 and the adhesive layer 910 may be removed, and thus the first to fourth conductive pillars 101a to 105 and the first and second connection pads 101b and 103b may be exposed.

Continuing to refer to FIG. 11, conductive posts 250 may be formed on the first and second connection pads 101b and 103b. Forming the conductive posts 250 may include forming a resist pattern having an opening, performing an electroplating process to fill the inside of the opening, and performing a strip process to remove the resist pattern. For example, the conductive posts 250 may have a diameter of about 5 μm to about 300 μm.

Subsequently, a photonics chip 200 and a bridge chip 300 may be mounted on the first molding layer 190. As described above, the photonics chip 200 may include fourth chip pads 221 on a lower surface thereof, and the bridge chip 300 may include fifth chip pads 321 on a lower surface thereof.

Mounting the photonics chip 200 and the bridge chip 300 may include forming second solder layers 255 between the fourth and fifth chip pads 221 and 321 and the first to fourth conductive pillars 101a to 105 corresponding thereto.

The fourth and fifth chip pads 221 and 321 may be bonded to the first to fourth conductive pillars 101a to 105 by the second solder layers 255. The first to third chip pads 111 to 131 may be connected to the first to fourth conductive pillars 101a to 105 by a thermo-compression bonding (TCB) manner.

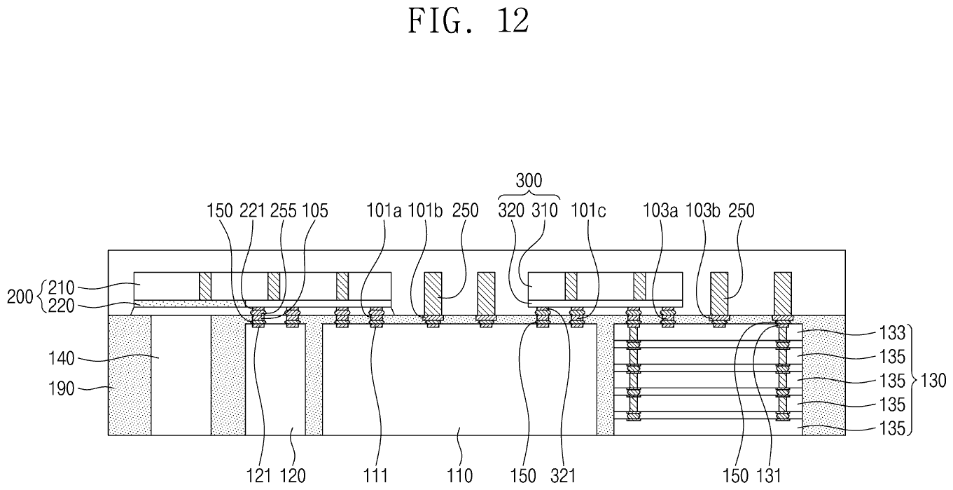

Referring to FIG. 12, a transparent underfill layer 270 formed of a transparent material may be formed between the photonics chip 200 and the first molding layer 190. The transparent underfill layer 270 may fill a space between the fourth chip pads 221.

Subsequently, a second molding layer 290 may cover the photonics chip 200, the bridge chip 300, and the conductive posts 250, on the first molding layer 190.

The second molding layer 290 may cover upper surfaces and sidewalls of the photonics chip 200 and the bridge chip 300 and upper surfaces and sidewalls of the conductive posts 250. The second molding layer 290 may be in direct contact with the first molding layer 190. The second molding layer 290 may include an insulating polymer such as, but not limited to, an EMC.

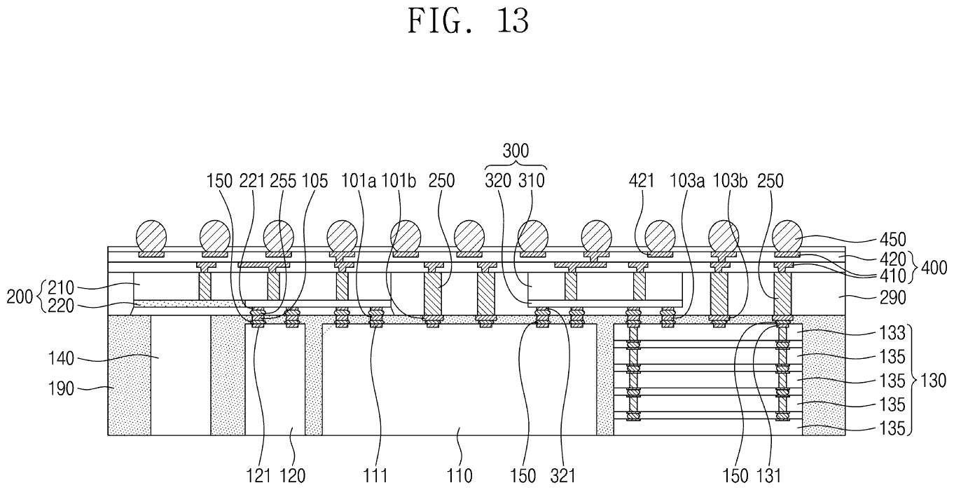

Referring to FIG. 13, a grinding process may be performed on the second molding layer 290, and thus a portion of the upper portion of the second molding layer 290 may be removed. The grinding process may be performed until the upper surfaces of the photonics chip 200 and the bridge chip 300 and the upper surfaces of the conductive posts 250 are exposed. The upper surface of the second molding layer 290 may be substantially coplanar with the upper surfaces of the photonics chip 200 and the bridge chip 300 and the upper surfaces of the conductive posts 250.

Subsequently, a redistribution layer 400 may be formed on the second molding layer 290. Forming the redistribution layer 400 may include repeatedly performing the deposition and patterning process of redistribution insulating layers 410 and the deposition and patterning process of conductive layers to form redistribution patterns 420 and connection pads 421.

Thereafter, connection terminals 450 may be provided on the connection pads 421 of the redistribution layer 400.

According to some embodiments of the present disclosure, the chip pads of the photonics chip and the chip pads of the first and second semiconductor chips, which are disposed to face each other, may be connected using the conductive pillars. Accordingly, the signal transmission path between the photonics chip and the first and second semiconductor chips may be reduced, and the semiconductor package may be further miniaturized.

While embodiments are described above, a person skilled in the art may understand that many modifications and variations are made without departing from the spirit and scope of the present disclosure defined in the following claims. Accordingly, the example embodiments of the present disclosure should be considered in all respects as illustrative and not restrictive, with the spirit and scope of the present disclosure being indicated by the appended claims.

What is claimed is:

1. A semiconductor package comprising:
a first semiconductor chip comprising first chip pads on a lower surface of the first semiconductor chip;
a photonics chip comprising a photonic integrated circuit and second chip pads on an upper surface of the photonics chip; and
first conductive pillars interposed between the first chip pads and the second chip pads.

2. The semiconductor package of claim 1, further comprising:
first solder layers between the first conductive pillars and the first chip pads; and
second solder layers between the first conductive pillars and the second chip pads.

3. The semiconductor package of claim 1, further comprising:
a first molding layer at least partially around the first semiconductor chip and the first conductive pillars; and
a second molding layer in contact with a lower surface of the first molding layer and at least partially around the photonics chip.

4. The semiconductor package of claim 3, further comprising:
a conductive post horizontally spaced apart from the photonics chip and at least partially penetrating the second molding layer; and
a connection pad coupled with at least one of the first chip pads and the conductive post.

5. The semiconductor package of claim 1, further comprising:
a redistribution layer on a lower surface of the photonics chip and comprising redistribution patterns coupled with the photonics chip; and
connection terminals on a lower surface of the redistribution layer.

6. The semiconductor package of claim 1, further comprising:
an optical support block horizontally spaced apart from the first semiconductor chip and at least partially vertically overlapping the photonics chip.

7. The semiconductor package of claim 6, wherein the photonics chip comprises an optical receiver coupled with the photonic integrated circuit, and
wherein the optical support block at least partially vertically overlaps the optical receiver.

8. The semiconductor package of claim 6, wherein a lower surface of the optical support block is substantially coplanar with lower surfaces of the first conductive pillars.

9. The semiconductor package of claim 1, further comprising:
a second semiconductor chip horizontally spaced apart from the first semiconductor chip and comprising third chip pads on a lower surface of the second semiconductor chip; and
second conductive pillars interposed between the second chip pads and the third chip pads.

10. The semiconductor package of claim 1, further comprising:
a third semiconductor chip horizontally spaced apart from the first semiconductor chip and comprising fourth chip pads on a lower surface of the third semiconductor chip; and
a bridge chip on the lower surfaces of the first semiconductor chip and the third semiconductor chip and comprising fifth chip pads on an upper surface of the bridge chip.

11. The semiconductor package of claim 10, further comprising:
fourth conductive pillars interposed between the fourth chip pads and the fifth chip pads.

12. The semiconductor package of claim 10, wherein the third semiconductor chip comprises vertically stacked memory chips.

13. A semiconductor package comprising:
a first semiconductor chip comprising first chip pads on a lower surface of the first semiconductor chip;
a second semiconductor chip horizontally spaced from the first semiconductor chip and comprising second chip pads on a lower surface of the second semiconductor chip;
a photonics chip on the lower surfaces of the first semiconductor chip and the second semiconductor chip and comprising third chip pads on an upper surface of the photonics chip;
an optical support block horizontally spaced apart from the first semiconductor chip and at least partially vertically overlapping the photonics chip;
first conductive pillars interposed between the first chip pads and the third chip pads;
second conductive pillars interposed between the second chip pads and the third chip pads;
a first molding layer at least partially around the first semiconductor chip, the second semiconductor chip, the first conductive pillars, and the second conductive pillars; and
a second molding layer in contact with a lower surface of the first molding layer and at least partially around the photonics chip.

14. The semiconductor package of claim 13, further comprising:
first solder layers between the first conductive pillars and the first chip pads; and
second solder layers between the first conductive pillars and the third chip pads.

15. The semiconductor package of claim 13, wherein an upper surface of the optical support block is substantially coplanar with upper surfaces of the first semiconductor chip and the second semiconductor chip.

16. A semiconductor package comprising:
a first semiconductor chip comprising first chip pads on a lower surface of the first semiconductor chip;
a second semiconductor chip horizontally spaced from the first semiconductor chip and comprising second chip pads on a lower surface of the second semiconductor chip;
a photonics chip on the lower surfaces of the first semiconductor chip and the second semiconductor chip and comprising a photonic integrated circuit and third chip pads on an upper surface of the photonics chip;
a third semiconductor chip horizontally spaced from the first semiconductor chip and comprising fourth chip pads on a lower surface of the third semiconductor chip;
a bridge chip on the lower surfaces of the first semiconductor chip and the third semiconductor chip and comprising fifth chip pads on an upper surface of the bridge chip;
first conductive pillars interposed between the first chip pads and the third chip pads;
second conductive pillars interposed between the second chip pads and the third chip pads;
third conductive pillars interposed between the fourth chip pads and the fifth chip pads;
a redistribution layer on lower surfaces of the photonics chip and the bridge chip and comprising redistribution patterns coupled with the photonics chip and the bridge chip;
a first molding layer at least partially around the first semiconductor chip, the second semiconductor chip, the third semiconductor chip, the first conductive pillars, the second conductive pillars, and the third conductive pillars;
a second molding layer in contact with a lower surface of the first molding layer and at least partially around the photonics chip, the bridge chip, and a conductive post; and
the conductive post horizontally spaced from the photonics chip and at least partially penetrating the second molding layer.

17. The semiconductor package of claim 16, further comprising:
an optical support block horizontally spaced from the second semiconductor chip and at least partially vertically overlapping the photonics chip.

18. The semiconductor package of claim 17, further comprising:
a transparent underfill layer interposed between the optical support block and the upper surface of the photonics chip.

19. The semiconductor package of claim 16, wherein the second molding layer is in contact with the lower surface of the first molding layer.

20. The semiconductor package of claim 16, further comprising:
first solder layers between the first conductive pillars and the first chip pads; and
second solder layers between the first conductive pillars and the third chip pads.
